(19) United States
(12) Patent Application Publication
(10) Pub. No.: US 2015/0021726 A1
(43) Pub. Date: Jan. 22, 2015

(54) METHOD FOR PATTERNING A MAGNETIC TUNNEL JUNCTION STACK

(71) Applicant: IMEC VZW, Leuven (BE)

(72) Inventors: Tai Min, Wilsele (BE); Vasile PARASCHIV, Kessel-Io (BE); Werner BOULLART, Binkom (BE); Mihaela loana POPOVICI, Leuven (BE)

(21) Appl. No.: 14/333,320

(22) Filed: Jul. 16, 2014

(30) Foreign Application Priority Data
Jul. 16, 2013 (EP) 13176613.1
Jan. 8, 2014 (EP) 14150428.2

(51) Int. Cl. H01L 43/12; H01L 43/02

(52) U.S. Cl. CPC H01L 43/12; H01L 43/02
USPC 257/421; 438/3

(57) ABSTRACT

The disclosed technology generally relates to methods of fabricating magnetic memory devices, and more particularly to methods of forming a magnetic tunnel junction (MTJ) stack. In one aspect, a method of forming the MTJ includes providing an MTJ material stack comprising a ferromagnetic material and forming thereon a protective mask layer to cover an active area of the MTJ material stack. The method additionally includes incorporating a glass-forming element into exposed portions of the ferromagnetic material. The method additionally includes at least partially amorphizing the exposed portions of the ferromagnetic material, wherein at least partially amorphizing transforms the exposed portions of the ferromagnetic material into an electrical insulator.

### CROSS-REFERENCE TO RELATED APPLICATIONS

This application claims foreign priority to European patent application EP 13176613.1, filed on Jul. 16, 2013, and European patent application EP 14150428.2, filed Jan. 8, 2014, the contents of which are incorporated by reference herein in their entireties.

### BACKGROUND OF THE INVENTION

1. Field of the Invention

The disclosed technology generally relates to methods of fabricating magnetic memory devices, and more particularly to methods of patterning a magnetic tunnel junction (MTJ) stack.

2. Description of the Related Art

Magnetic random access memory (MRAM) is emerging as an alternative to conventional semiconductor memories such as SRAM, DRAM and/or flash memory. Compared to volatile memories such as SRAM and DRAM, MRAM can be advantageous because it can be designed to be non-volatile (e.g., data retention of >10 years). Compared to non-volatile memories such as flash memory used for storage application, MRAM can be advantageous because it can offer high endurance (e.g., greater than 10⁶ cycles of memory access).

As compared to field-switchable MRAM devices that were studied in the earlier part of the last decade, spin transfer torque magnetic random access memory, also referred to as spin-torque transfer magnetic random access memory (STT-MRAMs), have gained popularity in part due to their potential to be scaled to very small sizes. It has been recognized that scalability of STT-MRAMs can be limited by thermal stability, as well as by writability. Two different geometries, one with an in-plane magnetization direction and another one with an out-of-plane (perpendicular) magnetization direction, have been proposed. It has been suggested that, while the former may be implemented at entry level, the latter may be more promising to be implemented as a more scalable geometry of the two different geometries of magnetic tunnel junction (MTJ) cells, especially from switching and thermal stability perspectives.

A STT-MRAM device typically includes a magnetic tunnel junction (MTJ) element which in turn includes a dielectric tunnel barrier layer sandwiched between a ferromagnetic hard layer (also referred to as a fixed magnetic layer, a reference layer, and a pinned layer) and a ferromagnetic soft layer (also referred to as a free layer). The MTJ element can be in a bottom-pinned MTJ stack, in which the bottom ferromagnetic layer corresponds to the hard layer and the top ferromagnetic layer corresponds to the soft layer. On the other hand, in a top pinned MTJ stack, the bottom ferromagnetic layer corresponds to the soft layer and the top ferromagnetic layer corresponds to the hard layer. The direction of magnetization of the hard layer is fixed, whereas the direction of magnetization of the soft layer can be changed by passing a drive current through it, which drive current is spin-polarized by the magnetization of the hard layer. When the direction of magnetization of the hard layer and the soft layer are parallel, the MTJ element is in low resistance. When the direction of magnetization of the hard layer and the soft layer are antiparallel, the MTJ element is in high resistance.

The fabrication process of a MTJ element typically involves the deposition of a stack of layers (hard layer, tunneling barrier layer and soft layer) followed by patterning the stack of layers. Patterning the MTJ element is one of the most critical aspects of fabrication in MRAM technology, as this involves etching portions of the stack of layers whereby almost all the layers used in such a stack form nonvolatile by-products. The etching process may thus leave residues on the patterned layers, which can cause, for example, electrical shorting, corrosion and degradation of the MTJ element. The deposition of the residues on the sidewalls of the MTJ element can be detrimental to the memory device performance. US patent application US2005/0277206 describes a method for patterning a MTJ element wherein part of the soft layer is made inactive by implantation of oxygen elements. By implanting oxygen ions into part of the soft layer, this implanted part is transformed from a ferromagnetic material into an oxide material. The patterning method according to US2005/0277206 forms a so-called ‘oxidation-only’ dielectric material at the side parts of the soft layer.

There is thus a need for improved method of patterning a MTJ element, which method doesn't suffer from one or more of the deficiencies of the state-of-the-art.

### SUMMARY OF CERTAIN INVENTIVE ASPECTS

In a first aspect, the disclosed technology relates to a method of patterning a magnetic tunneling junction (MTJ) element, the method comprising providing a stack of layers on a substrate, the stack of layers comprising a tunneling barrier layer sandwiched between a top ferromagnetic layer and a bottom ferromagnetic layer; defining outer parts surrounding a middle part for each of the layers; incorporating metal or metalloid elements Z together with ion elements E into the outer parts of the top ferromagnetic layer thereby modifying the ferromagnetic properties of the outer parts of the top ferromagnetic layer into insulating properties.

According to some embodiments, the bottom ferromagnetic layer comprises outer parts surrounding a middle part and the method further comprises also incorporating the metal or metalloid elements Z together with the ion elements E into the outer parts of the bottom ferromagnetic layer thereby modifying the ferromagnetic properties of the outer parts of the bottom ferromagnetic layer into insulating properties.

The ferromagnetic properties of the middle part of the top ferromagnetic layer and optional bottom ferromagnetic layer remain unchanged as no metal or metalloid elements Z and ion elements E are incorporated in this middle part.

According to some embodiments, insulating properties are amorphous glass-like properties.

According to some embodiments, the top ferromagnetic layer is a soft layer and the bottom ferromagnetic layer is a hard layer, or vice versa.

According to some embodiments, incorporating metal or metalloid elements Z together with ion elements E comprises providing a metal layer on the top ferromagnetic layer, the metal layer comprising the metal or metalloid elements Z; implanting the ion elements E into the metal layer and diffusing or driving (part of) the metal or metalloid elements Z and the ion elements E into the underlying outer parts of the top ferromagnetic layer and optional also into the underlying outer parts of the bottom ferromagnetic layer.

According to some embodiments, the method further comprises an annealing step after the step of incorporating the ion elements E and the metal/metalloid elements Z. The annealing step may be done locally to the outer parts of the stack of layers.

According to some embodiments, the annealing step is a laser annealing step.

According to some embodiments, the method of patterning a MTJ element further comprises, after providing the stack of layers and before incorporating the metal or metalloid elements together with the ion elements E, providing a hard mask on the middle part of the top ferromagnetic layer. This hard mask can be formed by, e.g., depositing a hard mask layer on the top ferromagnetic layer and patterning the hard mask layer thereby exposing the outer parts of the top ferromagnetic layer.

According to some embodiments, the ion elements E are implanted using a gas cluster ion beam (GCIB) implantation process.

According to some embodiments, the ion elements E are chosen from nitrogen N, oxygen O, fluorine F or a mixture thereof.

According to some embodiments, the metal or metalloid elements Z are chosen from glass network formers or glass network intermediates or a mixture thereof.

According to some embodiments, glass network formers may be chosen from Si, Ge, P, V, As, B.

According to some embodiments, glass network intermediates may be chosen from Al, Sb, Zr, Ti, Pb, Be, Zn.

According to some embodiments, the stack of layers is patterned after incorporating metal or metalloid elements Z together with ion elements E or after the annealing process. Part of the outer parts of the stack of layers is thus removed. These parts can be removed by etching. Preferably a reactive ion etch is used.

According to some embodiments, part of outer parts of the top ferromagnetic layer may already be removed before the step of incorporating metal or metalloid elements Z together with ion elements E. In this way the outer parts of the top ferromagnetic layer are thinned.

According to some embodiments, incorporating metal or metalloid elements Z together with the ion elements E into the outer parts of the top (and optional also bottom) ferromagnetic layer comprises implanting metal or metalloid elements Z and implanting the ion elements E into the outer parts of the top (and optional also bottom) ferromagnetic layer. In some embodiments, the outer parts of the top ferromagnetic material comprising ferromagnetic elements FM1 are converted at least partially into an at least partially amorphous glass-like insulating metal/metalloid layer, which can be represented as FM1ZₓE_{z}, where 0<x,z<1. In some other embodiments, the outer parts of the bottom ferromagnetic material comprising ferromagnetic elements FM2 are additionally converted at least partially into an amorphous glass-like insulating metal/metalloid layer, which can be represented as FM2ZₓE_{z}, where with 0<x,z<1. The converted ferromagnetic material thus comprises a mixture of ferromagnetic elements FM1 (or FM2), metal or metalloid elements Z and ion elements E.

According to some embodiments, the ferromagnetic material of the top ferromagnetic layer and the bottom ferromagnetic layer are the same (i.e. FM1=FM2).

According to some embodiments, incorporating metal or metalloid elements Z together with the ion elements E further comprises diffusing the metal or metalloid elements Z and the ion elements E into the underlying outer parts of the bottom ferromagnetic layer.

According to some embodiments, the at least partially amorphous insulating metal/metalloid layer FM1ZₓE_{z} and FM2ZₓE_{z} can include any one or more of an amorphous insulating metal/metalloid-oxide, which can be represented as FM1ZₓO_{z} and FM2ZₓO_{z}, respectively, an amorphous metal/metalloid-fluoride, which can be represented as FM1ZₓF_{z} and FM2ZₓF_{z}, respectively, and a metal/metalloid-nitride, which can be represented as FM1ZₓN_{z} and FM2ZₓN_{z}, respectively, where 0<x,z<1. In some other embodiments, the amorphous insulating metal/metalloid layer can be a mixture, such as, for example, a metal/metalloid-oxynitride, a metal/metalloid oxyfluoride, or a metal/metalloid fluoronitride.

A second inventive aspect relates to a magnetic tunneling junction (MTJ) element. The magnetic tunneling junction (MTJ) element comprises a stack of layers on a seed layer, the stack of layers comprising a tunneling barrier layer sandwiched in between a top ferromagnetic layer and a bottom ferromagnetic layer characterized in that the top ferromagnetic layer comprises a middle part and two outer parts aside of and surrounding the middle part, the middle part being ferromagnetic and comprising ferromagnetic elements FM1 while the outer parts are at least partially amorphous and have glass-like and insulating properties, and include a mixture of ferromagnetic elements FM1, ion elements E and metal/metalloid elements Z.

According to some embodiments of the second inventive aspect the bottom ferromagnetic layer comprises a middle part and two outer parts aside of and surrounding the middle part, the middle part being ferromagnetic and comprising ferromagnetic elements FM2 and the outer parts being amorphous glass-like insulating and comprising a mixture of ferromagnetic elements FM2, ion elements E and metal/metalloid elements Z.

According to some embodiments the ion elements E are chosen from oxygen O, nitrogen N and fluorine F or a mixture thereof.

According to some embodiments the metal or metalloid elements Z are chosen from glass network formers or glass network intermediates or a mixture thereof.

According to some embodiments, glass network formers may be chosen from Si, Ge, P, V, As, B.

According to some embodiments, glass network intermediates may be chosen from Al, Sb, Zr, Ti, Pb, Be, Zn.

According to yet another aspect, a method of forming a magnetic tunnel junction (MTJ) includes providing an MTJ material stack comprising a ferromagnetic material and forming thereon a protective mask layer to cover an active area of the MTJ material stack. The method additionally includes incorporating a glass-forming element into exposed portions of the ferromagnetic material. The method additionally includes at least partially amorphizing the exposed portions of the ferromagnetic material, wherein at least partially amorphizing transforms the exposed portions of the ferromagnetic material into an electrical insulator. The glass-forming element can be chosen from one of glass network formers or a glass network intermediates described above, which can be a metal or a metalloid element. The glass-forming element is chosen from the group consisting of Si, Ge, P, V, As, B Al, Sb, Zr, Ti, Pb, Be and Zn. In some other embodiments, the method further includes incorporating an oxidizing element chosen from the group consisting of oxygen (O), nitrogen (N) and fluorine (F), wherein incorporating the oxidizing element forms a glass having an amorphous network comprising the glass-forming element, the oxidizing element and an element of the ferromagnetic material. In some other embodiments, the at least one of the oxidizing element and the glass-forming element is implanted into the ferromagnetic material. In some other embodiments, the MTJ material stack further includes a bottom ferromagnetic material and a dielectric tunneling barrier interposed between the ferromagnetic material and the bottom ferromagnetic material, and the method further includes at least partially amorphizing a portion the bottom ferromagnetic material overlapping with the exposed portions of the ferromagnetic material, thereby transforming the portion of the bottom ferromagnetic material into an electrical insulator.

It is an advantage of the present disclosure that a high quality insulating material is formed such that the final MTJ stack has improved thermal stability, improved reliability, minor or no leakage through the insulating material.

It is an advantage of the present disclosure that there is no need to etch the complete MTJ stack by modifying part of the ferromagnetic layer (i.e. the soft layer for bottom pinned stacks or the hard layer for top pinned stacks) of the MTJ stack into an insulating material with low current density. The current density of the modified part of the ferromagnetic layer is preferably lower than 10⁻⁶ A/cm² even more preferably lower than 10⁻⁹ A/cm².

It is an advantage of different embodiments of the present disclosure that an at least partially amorphous glass-like insulating region is formed at outer parts of the soft layer of the MTJ element.

It is an advantage of different embodiments of the present disclosure that no detrimental etching steps of the ferromagnetic material are necessary for patterning the MTJ element.

It is an advantage of different embodiments of the present disclosure that by using a patterning method according to embodiments a precise control of size and shape of the MTJ element is achieved.

It is an advantage of different embodiments of the present disclosure that by using a patterning method according to embodiments contamination of the patterned MTJ element is reduced compared to prior art patterning techniques.

It is an advantage of different embodiments of the present disclosure that by using a patterning method according to embodiments the patterned MTJ element is less prone to electrical shorting.

It is an advantage of different embodiments of the present disclosure that by using a patterning method according to embodiments deterioration of the MTJ element is reduced.

### BRIEF DESCRIPTION OF THE DRAWINGS

The disclosure will be further elucidated by the following description and the appended Figures.

FIGS. 1 to 6 are schematic representations of various stages of patterning a MTJ element according to embodiments of the present disclosure.

FIG. 7 is a flowchart illustrating a method of patterning a MTJ element according to embodiments of the present disclosure.

FIGS. 8 to 11 are schematic representations of various stages of patterning a MTJ element according to embodiments of the present disclosure.

FIG. 12 is a flowchart illustrating a method of patterning a MTJ element according to embodiments of the present disclosure.

FIGS. 13 to 16 are schematic representations of various stages of patterning a MTJ element according to embodiments of the present disclosure.

### DETAILED DESCRIPTION OF CERTAIN ILLUSTRATIVE EMBODIMENTS

The disclosure will be further elucidated by the following detailed description of several embodiments of the disclosure and the appended figures.

In the following detailed description, numerous specific details are set forth in order to provide a thorough understanding of the disclosure and how it may be practiced in particular embodiments. However, it will be understood that the present disclosure may be practiced without these specific details. In other instances, well-known methods, procedures and techniques have not been described in detail, so as not to obscure the present disclosure. While the present disclosure will be described with respect to particular embodiments and with reference to certain drawings, the disclosure is not limited hereto. The drawings included and described herein are schematic and are not limiting the scope of the disclosure. It is also noted that in the drawings, the size of some elements may be exaggerated and, therefore, not drawn to scale for illustrative purposes.

The term “comprising,” used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B.

When reference is made to conductor, dielectric and insulator (or conductive, dielectric and insulating), the difference is defined relating to their electrical conductance. The current which can pass through reduces from conductor to dielectric and from dielectric to insulator. The conductance of a conductor is higher than the conductance of a dielectric and the conductance of a dielectric is higher than the conductance of an insulator. Otherwise said, the current density for an insulator is thus lower than the current density for a dielectric and the current density for a dielectric is lower than the current density for a conductor. Current density through an insulator should be less than 10⁻⁶ A/cm², even less than 10⁻⁹ A/cm². Current density through a dielectric is typically between 10⁻⁴ A/cm² and 10⁻⁶ A/cm².

As used herein, a glass refers to a material that does not have long range or periodic order. Whereas crystals have a regular, repeating structure, glasses lack the long range order of a crystal. Glasses do generally have, however, networks having short range order. A glass network includes a glass-forming element. As used herein, a glass-forming element can refer to a network former and/or a network intermediate. Without being bound to any theory, at least in the context of oxide-based glasses, network formers refer to elements that can form a glass on their own, and are generally directly incorporated into the network. In addition, network intermediates refer to elements that assist in glass formation and can be incorporated into the network. In contrast, network modifiers generally are not incorporated directly into the network of bonds, and thus force the network to be formed around them. For example, for oxide-based glasses, network formers can include Si, Ge, P, V, As, B Al, V, Sb and Zr, among other elements, and network modifiers can include Ti, Pb, Be, Zn, Cd, As, Sb and Th, among other elements. Depending on the actual composition of the particular glass, however, an element can be classified as either a network former or a network modifier. For example, Al, Sb and Zr can be classified as either a network former or a network modifier, depending on the circumstances. These general concepts can be found in, for example, Shelby, Chapter 5 from R. K. Brow as retrieved from http://web.mst.edu/˜brow/PDF_structure1.pdf for the theoretical background and definition of glass, glass network formers, glass network intermediates and glass network modifiers.

As used herein, an amorphous material or an amorphized material refers to a material that does not have long range or periodic order, similar to glasses. It will be appreciated, however, that an amorphous material may or may not have well-defined networks having short range order. For example, bombardment of a target material with energetic atoms or ions, such as might occur in ion implantation, can amorphize the target material. However, such amporphization does not necessarily result in formation of a glass.

As used herein, a metalloid element refers to an element chosen from the group that includes boron (B), silicon (Si), germanium (Ge), arsenic (As), antimony (Sb), tellurium (Te) and combinations thereof.

The starting point in the methods for patterning a MTJ stack according to the present disclosure is a ferromagnetic layer such as, for example, a CoFeB layer. The current density through such a ferromagnetic layer is about 10⁴ A/cm². By incorporating only oxygen elements, as in US2005/0277206, the ferromagnetic layer can be oxidized and converted into an oxide. For example, CoFeB can be converted into CoₓFe_{y}O_{z}. The ferromagnetic material is then transformed to an oxide with current density properties about 10⁻⁶ A/cm². The inventors of the present applications have surprisingly found that, by additionally incorporating metal/metalloid elements Z to the ferromagnetic layer FM according to embodiments of the present disclosure, together with ion elements E, the ferromagnetic material can be transformed into a higher quality at least partially amorphous insulating matrix, which can be represented as FMZ_{X}E_{Z}. The current density through the resulting at least partially amorphous insulator has been found to be less than 10⁻⁶ A/cm² or even less than 10⁻⁹ A/cm².

It is an advantage of the present disclosure that there is no need to etch the complete stack of the MTJ element 1 to form an insulated MTJ stack thanks to the modification of part of the ferromagnetic layer (i.e. the soft layer for bottom pinned stacks or the hard layer for top pinned stacks) of the MTJ stack into a stable and high quality insulator metal/metalloid-oxide-like or metal/metalloid-fluoride-like or metal/metalloid-nitride-like matrix. Thus formed high quality metal/metalloid-oxide-like or metal/metalloid-fluoride-like matrix or metal/metalloid-nitride-like is also very stable for subsequent (high temperature) annealing steps in the further processing of the MRAM device comprising the patterned MTJ stack.

For illustrative purposes only, without limiting the scope of the present invention, certain inventive aspects of the disclosed technology may be described using a bottom-pinned MTJ element, wherein the bottom ferromagnetic layer is the hard layer and the top ferromagnetic layer is the soft layer. In some embodiments, the hard layer may comprise multiple layers such as, for example, a fixed magnetic layer 101a on a pinning layer 101b. It will be appreciated, however, that the top and bottom ferromagnetic layers may be interchanged, such as may be the case, for example, for a top-pinned MTJ stack. Otherwise said, the order of the soft layer, the tunneling barrier layer and the hard layer can be reversed.

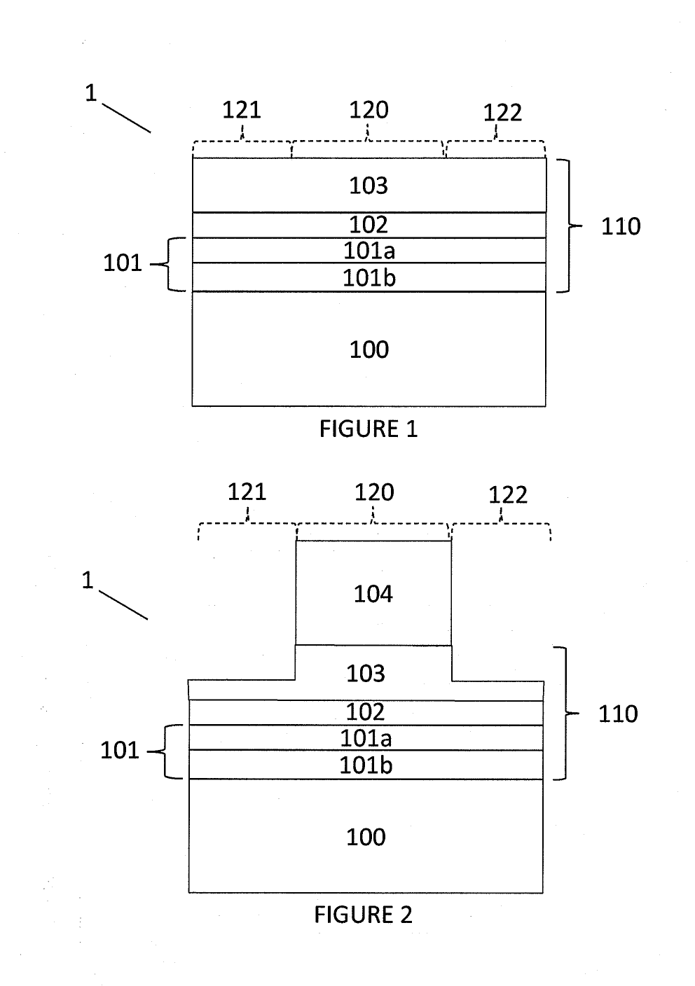

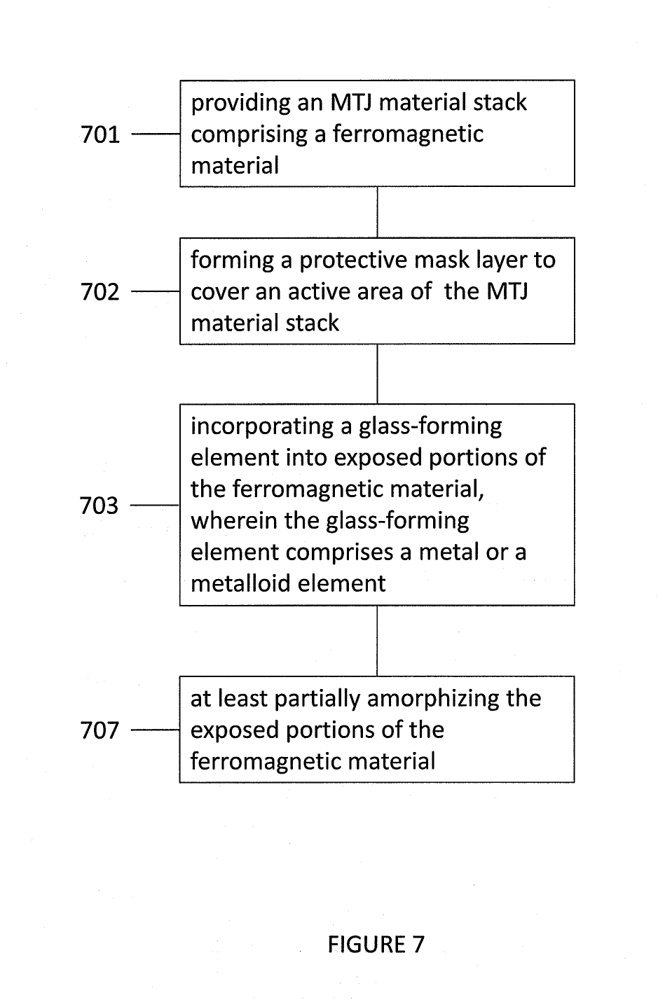

FIG. 7 is a flowchart describing a method of forming a magnetic tunneling junction (MTJ) element according to embodiments of a first aspect. The method of forming the MTJ element includes providing 701 an MTJ material stack comprising a ferromagnetic material. In some embodiments, the stack comprises a tunneling barrier layer interposed between a top ferromagnetic layer and a bottom ferromagnetic layer. The method additionally includes forming 702 a protective mask layer to cover an active area of the MTJ material stack. In embodiments, covering an active area of the MTJ material stack can include defining outer parts surrounding the active area that forms a middle part for each of the top ferromagnetic layer, the tunneling barrier layer, and the bottom ferromagnetic layer. The method additionally includes incorporating 703 a glass-forming element into exposed portions of the ferromagnetic material. In some embodiments, the glass-forming element includes a metal or a metalloid element (Z). In some other embodiments, incorporating 203 a glass-forming element includes incorporating the metal or the metalloid elements (Z) together with oxidizing elements, which can be ion elements (E), into the outer parts of the top ferromagnetic layer. The method additionally includes at least partially amorphizing 707 or modifying the exposed portions or the outer parts of the ferromagnetic material. At least partially amorphizing 707 can transform the exposed portions of the ferromagnetic material into an electrical insulator, or can modify the outer parts of the top ferromagnetic layer to have electrically insulating properties. Each of the processes of the method of FIG. 7 will now be described more in detail, in reference to FIGS. 1 to 6.

Referring to FIG. 1, a stack of layers 110 is provided on a substrate 100, according to some embodiments. A bottom ferromagnetic layer 101 is provided on the substrate 100. A tunneling barrier layer 102 is provided on the bottom ferromagnetic layer 101. A top ferromagnetic layer 103 is provided on the tunneling barrier layer 102. There may be additional layers present in between the tunneling barrier layer 102 and the top and/or bottom ferromagnetic layer 101, 103, such as for example spin-polarizing layers as known to a person skilled in the art. The thickness of the stack, in particular of the layer or layers to be removed during patterning, should preferably be kept as small as possible. The thicker the stack, the more difficult it is to remove all the layers together. All of the layers in the MTJ element described herein may be formed in a deposition system such as, for example, in (but not limited to) a physical vapor phase deposition (PVD) system.

The substrate 100 may include a seed layer (not shown) according to some embodiments. A seed layer may include, for example, Ta, Ru, or other conductive materials. The stack of layers 110 includes a tunneling barrier layer 102 sandwiched between a bottom ferromagnetic layer 101 and a top ferromagnetic layer 103. Each of the bottom ferromagnetic layer 101 and the top ferromagnetic layer 103 may be a single ferromagnetic layer such as, for example, CoFeB, or may comprise a stack with alternating (magnetic metal)/(non-magnetic metal) layers repeated n times, for example (Co/Pt)ₙ (n>=1) or with (magnetic metal)/(magnetic metal) layers repeated n times, for instance (Co/Ni)ₙ (n>=1), according to embodiments. In some embodiments, bottom ferromagnetic layer 101 and the top ferromagnetic layer 103 may include the same ferromagnetic material or materials. In some embodiments, the tunneling barrier layer 102 is formed of MgO. In some other embodiments, other insulating materials may be used for the tunneling barrier layer, such as, for example, AlₓO_{y}, TiₓO_{y}, and ZnₓO_{y} (0<x,y), among other insulating materials.

In some embodiments, each of the layers of the stack 110 may be masked, e.g., hard-masked, into a middle part 120 and two outer parts 121, 122 at each side of (and next to) the middle part 120, as shown in the cross section of FIG. 1. While not apparent in the cross-sectional view of FIG. 1, middle part 120 is surrounded by the outer parts 121, 122, according to some embodiments. Throughout the description, for the top ferromagnetic layer 103 there may be referred to the middle top part and two outer top parts. For the bottom ferromagnetic layer 101 there may be referred to the middle bottom part and two outer bottom parts. For the tunneling barrier layer 102 there may be referred to the middle tunneling part and two outer tunneling parts.

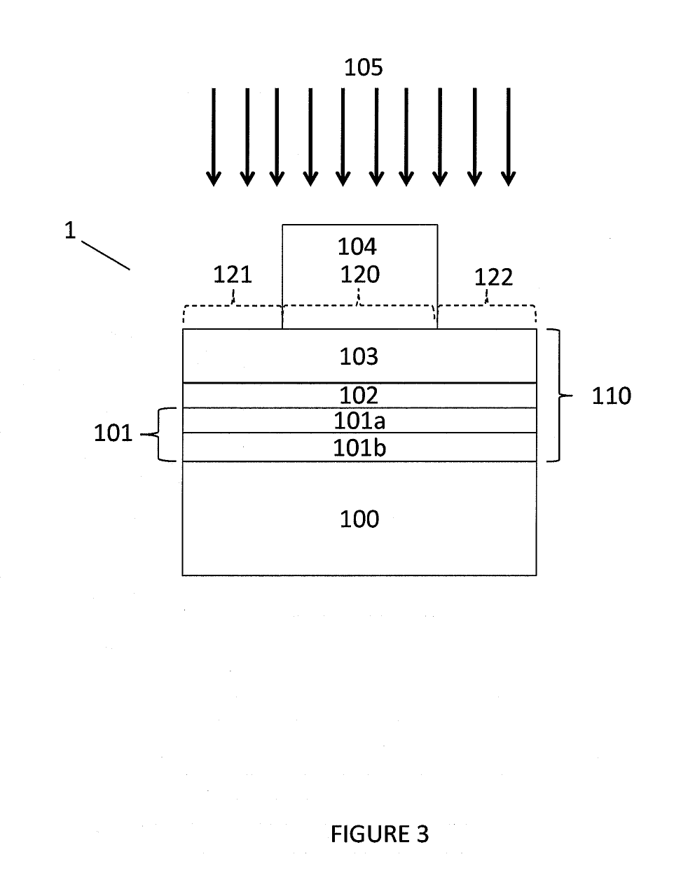

Referring to FIGS. 2 and 3, according to embodiments, each of the layers of the stack 110 may be masked using a patterned hard mask 104 that is provided on the stack of layers 110 (FIGS. 2,3). The hard mask 104 may be formed using standard techniques such as using, for example, photoresist and lithography. The patterned hard mask 104 is present only on the middle part 120 of the stack of layers 110, more precisely on the middle part of the top ferromagnetic layer 103. The outer parts 121,122 of the stack of layers (more specifically the outer parts of the ferromagnetic layer) remain thus exposed.

The hard mask 104 may be formed of, for example, an oxide or another suitable material which will protect the underlying middle part 120 of the stack of layers during the following processes. Afterwards this hard mask may be removed. Alternatively, the hard mask 104 may be formed of a conductive material such as a metal. In some embodiments, the hard mask 104 may remain in the final memory device and may become part of the top electrode of the MTJ element. The hard mask 104 should be thick enough such that the metal elements Z do not diffuse to the underlying layers via the hard mask. Thus, depending on the material of the hard mask, the hard mask can remain on the MTJ element or can be removed in one of the later processes (after the incorporation of the metal/metalloid elements Z and ion elements E).

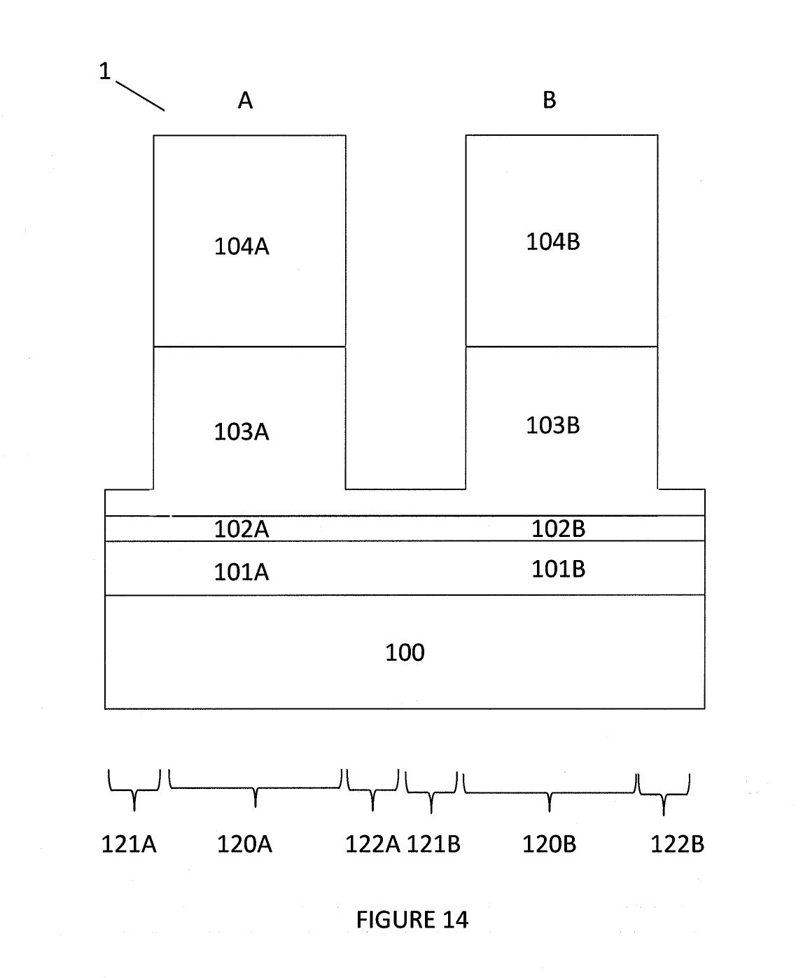

In some embodiments, materials of the outer parts 121, 122 of the top ferromagnetic layer 103 may be selectively removed before the conversion step (203, 204) using the hard mask 104 (FIG. 2, FIG. 14) to reduce the layer thickness. Upper part of the outer parts 121, 122 of the top ferromagnetic layer 103 may be removed via etching, e.g., via reactive ion etching. It can be advantageous for thick top ferromagnetic layers to etch already part of the top parts before the conversion step. For example, the entire thickness of a top ferromagnetic layer 103 that is relatively thick could be more difficult to convert into amorphous glass-like insulator material because, the conversion may be limited by diffusion of atoms of the metal/metalloid and ion elements into the layer. If the bottom ferromagnetic layer needs to be converted also, the depth through which the metal/metalloid Z and ion elements E need to diffuse is even deeper. In order to have the metal/metalloid Z and ion elements E diffused through all the needed layers, a high thermal budget or high implantation energies may be necessary, which can be detrimental for the device characteristics of the stack. Therefore, part of the outer parts of the top ferromagnetic layer 103 may be removed prior to the conversion to thin down the top ferromagnetic layer 103.

After providing the hard mask 104, metal and/or metalloid elements Z together with ion elements E are incorporated into the outer parts 121, 122 of the top ferromagnetic layer 103, thereby modifying the outer parts of the top ferromagnetic layer 103 to have electrically inactive, i.e. insulating properties. In some embodiments, these elements can be incorporated by ion implantation 105. The exposed outer parts 121, 122 of the top ferromagnetic layer are exposed to an ion implantation 105 of ion element(s) E and metal/metalloid element(s) Z (FIG. 3). The metal/metalloid elements Z are chosen such that the resulting converted outer parts of the top ferromagnetic layer form a high quality insulator formed of at least partially amorphous glass. The metal/metalloid element Z is preferably chosen from glass network formers such as Si, Ge, P, V and As, among other network formers, or from glass network intermediates such as Al, Sb, Zr, Ti, Pb, Be and Zn, among other intermediates, or a mixture thereof. According to embodiments, different metal elements Z (Z1, Z2, . . . ) may be incorporated. Preferably, one metal/metalloid element Z is used. Ion elements E may be chosen from oxygen (O), nitrogen (N), fluorine (F) or a mixture thereof. The outer parts may be converted into a metal/metalloid-oxide (FMZ_{X}O_{Z}) or metal/metalloid-fluoride (FMZ_{X}F_{Z}) or metal/metalloid-nitride (FMZ_{X}N_{Z})), depending on the ion elements E used, where 0<x,y.

Thus, according to various embodiments, the combination of the ion elements E and the metal/metalloid elements Z enables glass formation and formation of an at least partially amorphous glass-like insulator in the ferromagnetic layer. The insulating properties of such high quality at least partially amorphous glass-like insulator are higher than the dielectric properties of the dielectric formed using the method of US2005/0277206.

According to embodiments, species containing metal/metalloid elements are implanted together, e.g., simultaneously co-implanted or sequentially implanted, with species containing atoms of oxygen, fluorine or nitrogen into outer parts of the ferromagnetic layer. According to embodiments, implantation may be performed into both the outer parts of the top ferromagnetic layer 103 and into the outer parts of the bottom ferromagnetic layer 101.

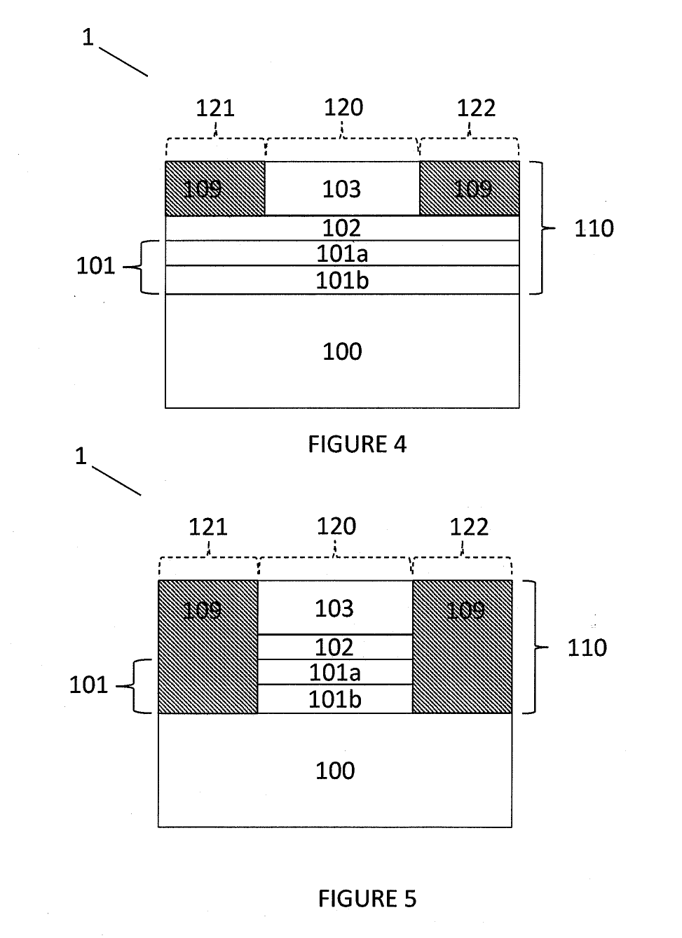

Referring to FIG. 4, the outer parts 109 of the top ferromagnetic layer 103 (and the outer parts of the bottom ferromagnetic layer 101 if also implanted as illustrated in FIG. 5) are thereby made electrically inactive and transformed into a stable metal/metalloid-oxide/nitride/fluoride material 109 with improved insulating properties. The middle part 120 of the top ferromagnetic layer 103 remains thus ferromagnetic and not altered, converted or otherwise transformed (FIG. 4). The middle part of the bottom ferromagnetic layer also remains ferromagnetic and not altered, converted or otherwise transformed (FIG. 5).

Referring to FIG. 5, according to some embodiments, the bottom ferromagnetic layer 101 may additionally be partially transformed to an insulating material by incorporation of metal/metalloid elements Z together with ion elements E into outer parts of the bottom ferromagnetic layer 101. The outer parts 110 of the bottom ferromagnetic layer are thereby made electrically inactive and transformed into a stable metal/metalloid insulator 109. The stable metal/metalloid insulator 109 may be a stable metal/metalloid-oxide or metal/metalloid-fluoride material or metal/metalloid-nitride material or a mixture thereof with much better insulating properties compared to prior art. The middle bottom part of the bottom ferromagnetic layer remains thus ferromagnetic and is not altered. The MTJ element 1, after conversion of the outer parts of both the top 103 and bottom 101 ferromagnetic layers, is schematically shown in FIG. 5.

Alternative embodiments for incorporating the metal/metalloid elements Z together with ion elements E into outer parts of the ferromagnetic layers (into the top ferromagnetic layer according to some embodiments and additionally into the bottom ferromagnetic layer according to some other embodiments).

According to some embodiments, the ion elements E and metal/metalloid elements Z are implanted into the outer parts of the ferromagnetic layers. The ion elements E and the metal/metalloid elements Z may be implanted simultaneously in one implantation process (i.e., co-implantation) according to some embodiments, or may be implanted sequentially in separate implantation processes. The implantation process may be performed using a suitable ion beam technique. The tilt angle of the implantation process is preferably between 0 and 90 degrees.

Due to the ion implantation of ion elements E and metal/metalloid elements Z into the exposed outer parts of the exposed top ferromagnetic layer 103, the ferromagnetic properties of the outer parts of the top ferromagnetic layer 103 are modified into insulating properties. The outer parts of the top ferromagnetic layer 103 are thus modified to an oxide-matrix or fluoride-matrix or nitride-matrix or mixture thereof 109 comprising the initial ferromagnetic material of the top ferromagnetic layer 103, the implanted ion elements, such as oxygen O or fluorine F or nitrogen N, and the implanted metal/metalloid elements Z.

In some embodiments, after implantation, the amorphized metal/metalloid-oxide, metal/metalloid-fluoride or metal/metalloid-nitride or a mixture thereof in the outer parts 109 of the top ferromagnetic layer may be thermally annealed. A typical annealing condition would be laser anneal in the temperature range of 400 to 700 degrees Celsius. Diffusion of the metal/metalloid elements Z and the ion elements E take place both during the implantation step and the annealing step. The annealing step helps to further diffuse or drive the elements into the ferromagnetic layers after the implantation process. According to some embodiments, the annealing process may be a rapid thermal annealing process. According to some other embodiments, the annealing process is a localized thermal annealing process. A laser spike anneal may, for example, be used. It is an advantage of a localized annealing process, that only the important, i.e. the converted outer parts 109 of the MTJ stack are subject to the localized rapid thermal annealing process. The middle parts of the MTJ stack 110 are protected with a hard mask layer 104 such that they are not subject to the annealing process. By exposing the converted outer parts 109 to a localized rapid thermal annealing process, a high temperature may be reached for a short period of time duration which enables further diffusion of the elements into the ferromagnetic layers without degradation of the electrical device properties.

According to the present disclosure, the material of at least the outer parts of the top ferromagnetic layer 103 is converted from ferromagnetic into insulating material. According to embodiments also the outer parts of the bottom ferromagnetic layer 103 may be converted from ferromagnetic into insulating material. Also the outer parts the tunneling barrier layer may be converted from an insulating material into another insulating material due to the incorporation of additional elements (i.e. the metal/metalloid elements Z and the ion elements E). The tunnel barrier layer may thus alter into an intermixed insulating layer comprising the initial insulating material and additional elements.

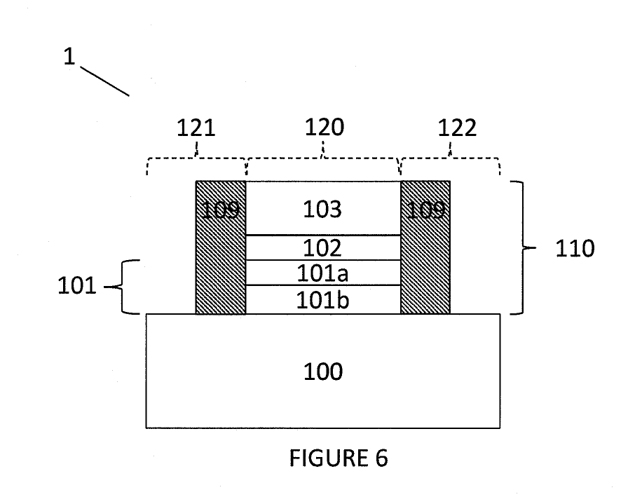

FIG. 6 shows schematically a MTJ stack 1 according to embodiments wherein the outer parts 121,122 of all the layers of the stack 110 are converted resulting in a smaller MTJ stack i.e. the middle part 120 of the initial stack of layers remains. The middle parts 120 of the different layers are thus not altered and ferromagnetic properties of the layers of the middle part remain unchanged.

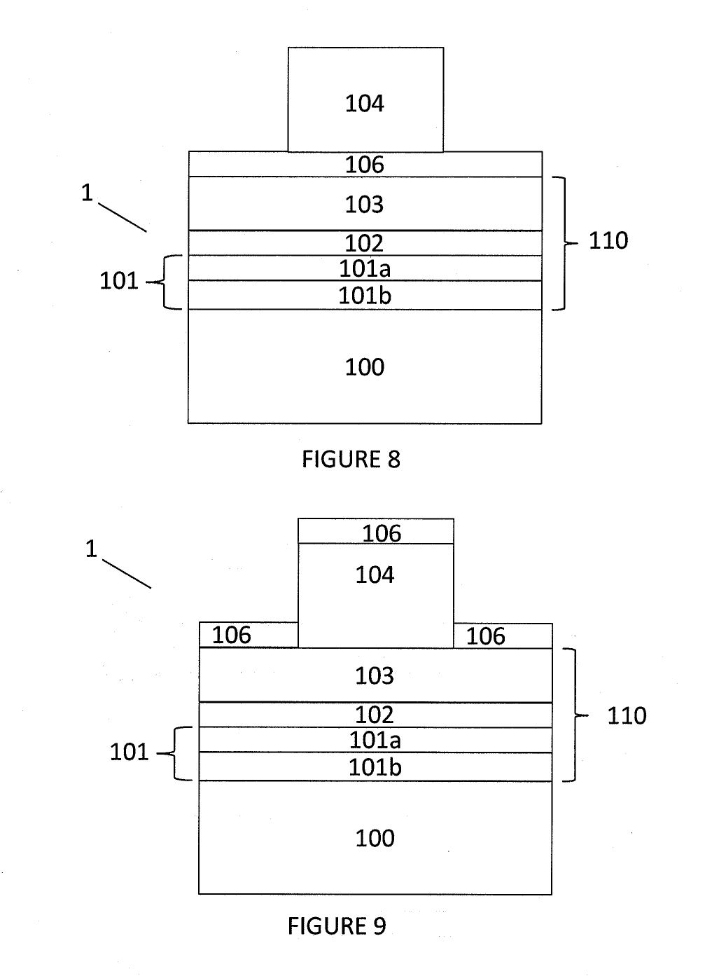

In the illustrated embodiment, after the conversion of the ferromagnetic layers, at least portions of the outer parts 121, 122 may be removed, e.g., etched, to reduce the width of the MTJ element 1. The partial removal of the outer parts 121, 122 may be performed, e.g., using a separate patterning process whereby an area covering the middle part 120 and contiguous portions of the outer parts 121, 122 are covered by a masking layer, e.g., photoresist layer and/or a hardmask layer. An exemplary final structure of the MTJ element after etching is shown in FIG. 6. As illustrated, portions of the converted ferromagnetic material the at least partially amorphous glass material 109 of the outer parts 121, 122 that are continuous with the middle part 120, remain present in the final MTJ element 1 in order to protect the middle part 102 of the ferromagnetic layers during further processes involving other etching or other detrimental processes.

Whereas for the embodiments relating to FIGS. 1 to 7, the ion elements E and metal/metalloid elements Z are incorporated by one or more implantation processes, the embodiments relating to FIGS. 8 to 12 describe the incorporation of these elements by a combination of a metal/metalloid layer and an implantation process.

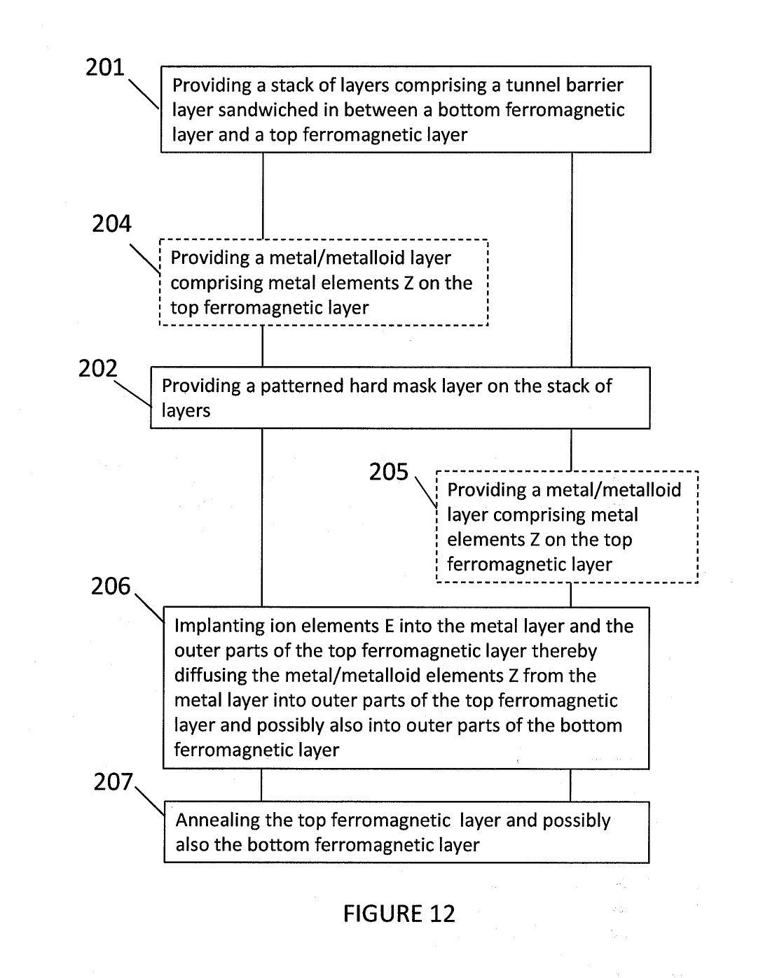

The flowchart of FIG. 12 describes different processes of a method of patterning a MTJ element according to some embodiments. The method includes providing 201 a stack of layers comprising a tunneling barrier layer sandwiched in between a bottom ferromagnetic layer and a top ferromagnetic layer. The method additionally includes providing 202 a patterned hard mask on the stack of layers. The method additionally includes providing 204. 205 a metal/metalloid layer comprising metal elements Z on the top ferromagnetic layer, whereby this layer can be formed prior to (204) or after (205) providing 204 the hard mask. The method additionally includes implanting 206 describes implanting ion elements E into the metal layer and outer parts of the top ferromagnetic layer, thereby diffusing the metal elements Z into outer parts of the top ferromagnetic layer, and optionally also into outer parts of the bottom ferromagnetic layer. The method further includes annealing 207 the top ferromagnetic layer and, preferably also the bottom ferromagnetic layer. Each of the processes of FIG. 12 will now be further elucidated in reference to FIGS. 8 to 12.

Referring to FIGS. 8 and 9, according to some embodiments, a metal/metalloid layer 106 is provided on the top ferromagnetic layer 101 of the stack of layers 110 (FIGS. 8, 9). The metal/metalloid layer 106 includes metal/metalloid elements Z 108 which are chosen such that a metal/metalloid-oxide (FMZ_{X}O_{Z}) or metal/metalloid-fluoride (FMZ_{X}F_{Z}) or metal/metalloid-nitride (FMZ_{X}N_{Z}) matrix is subsequently formed, resulting in an at least partially amorphous high quality glass-like insulator, which surrounds the reaming middle part 120 of the MTJ stack 110. The converted outer parts of the top ferromagnetic layer form a high quality insulator including an at least partially amorphous glass, as described above. The metal/metalloid layer 106 may be provided using standard deposition techniques. The metal/metalloid element Z is preferably chosen from glass network formers such as Si, Ge, P, V, As or glass network intermediates such as Al, Sb, Zr, ti, Pb, Be, Zn or a mixture thereof. The metal/metalloid layer 106 may thus for example be an Al-layer, a Ti-layer or a Ge-layer. The thickness of the metal/metalloid layer 106 should be selected in function of the thickness of the top ferromagnetic layer. The thicker the top ferromagnetic layer, the more metal/metalloid elements Z are needed to induce the conversion of the ferromagnetic material into insulating material, the thicker the metal/metalloid layer 106 preferably is. The thickness of the metal/metalloid layer 106 should preferably be in the range of about 1.5 nm to about 3 nm.

Referring to FIGS. 8 and 9, according to alternative embodiments, a hard mask 104 may be provided on the middle part 120 of the top ferromagnetic layer before (FIG. 9, step 204) or after (FIG. 8, step 205) providing the metal/metalloid layer 106. In the case the metal/metalloid layer 106 is provided on the hard mask 104 as illustrated in FIG. 9, no metal/metalloid layer may be present between the hard mask 104 and the top ferromagnetic layer 103 in the middle part 120. The hard mask 104 may be provided using standard patterning techniques such as using resist and lithography.

A main function of the hard mask layer 104 is to protect the middle part 120 of the top ferromagnetic layer 103 from the subsequent implantation and annealing step(s). The hard mask 104 is therefore present only on the middle part 120 of the stack of layers 110. The outer parts 121,122 of the stack of layers, and if already present the metal/metalloid layer 106, remains thus exposed. The hard mask 104 may include, for example nitride or an oxide or even a metal, according to various embodiments. In embodiments where the hard mask layer 104 includes a metal, the exposed top part of the hard mask 104 may possibly also be converted to another material during the conversion step. As the hard mask layer 104 is thick enough, this does not form any problem for the further processing of the device. The MTJ stack 110 typically has a maximum thickness to be converted that is smaller than the thickness of the hard mask 104. By way of example, in implementations where about 10 nm of the top ferromagnetic layer 103 is to be converted, similar thickness of about 10 nm of the metal hard mask 104 would be converted. That is, a hard mask 104, which typically has a thickness (e.g., 80 nm) exceeding the thickness of the ferroelectric layer 103 to be converted, has sufficient thickness to prevent the material in the middle part from being affected.

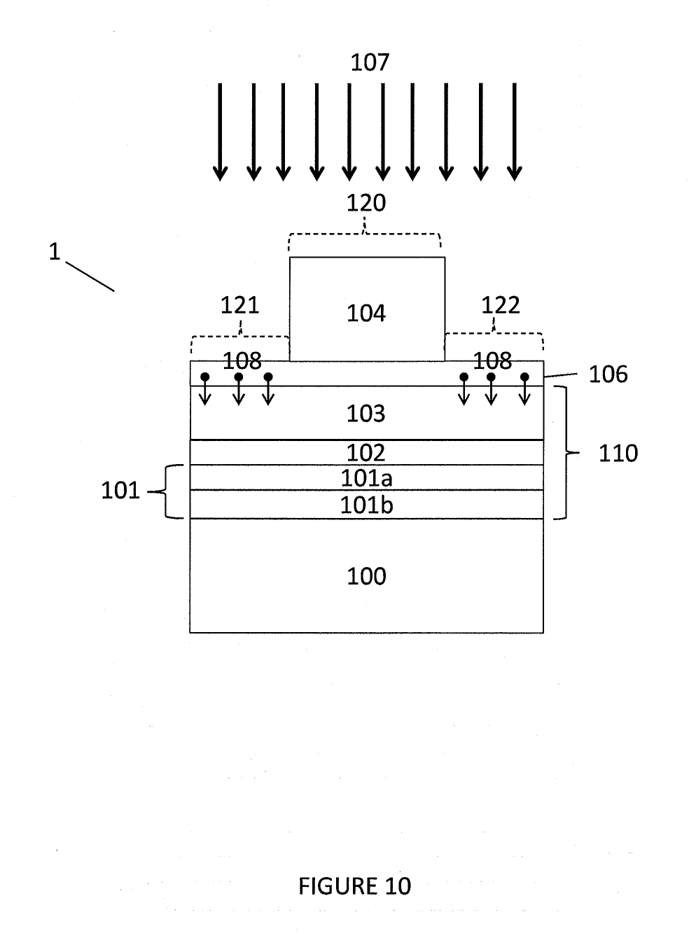

Referring to FIG. 10, after providing the hard mask 104, the exposed outer parts 121,122 of the top ferromagnetic layer 103 are implanted with ion beam 107 comprising accelerated ion elements E, according to some embodiments. The inventors have found that implantation with the ion beam 107 having accelerated ion elements E results in at least some of the atoms of the metal/metalloid elements Z 108 of the metal/metalloid layer 106 being incorporated into the top ferromagnetic layer 103 through the exposed outer parts of the underlying top ferromagnetic layer 103, thereby modifying the ferromagnetic properties of the outer parts of the underlying top ferromagnetic layer 103 to have insulating properties. The outer parts of the top ferromagnetic layer 103 are thus modified to form an at least partially amorphous material 109, or a matrix, e.g. an oxide-matrix or fluoride-matrix or nitride matrix, comprising the initial ferromagnetic material FM from the top ferromagnetic layer 103, the implanted ion elements E, e.g. O, N, F, and the metal/metalloid elements Z diffused from the metal/metalloid layer 106.

Without being bound to theory, in some embodiments, the elements Z 108 of the metal/metalloid layer 106 may be incorporated into the underlying ferromagnetic layer 103 through forward scattering of the atoms of the ferromagnetic layer 103 when bombarded by the accelerated ion elements E of the ion beam 107. In forward scattering, the momentum of an incident accelerated ion is transferred to atoms of a target material, thereby resulting in the target atoms being displaced, or forward scattered, from their original lattice site. Thus displaced target atoms mix with preexisting atoms in the location that the target atoms are scattered to. The process is sometimes referred to as ion beam mixing.

The implantation process may be done using for example ion beam techniques. The tilt angle of the implantation process is preferably between 0 and 90 degrees.

The metal/metalloid Z elements of the metal layer 106 are chosen such that they form an at least partially amorphous, insulating, mixed glass-like insulator together with the ion elements E and the ferromagnetic material FM. The metal/metalloid element Z may be chosen from so-called glass network formers, such as for example Si, Ge, P, V, or As, or so-called glass network intermediates, such as for example Al, Sb, Zr, Ti, Pb, Be, or Zn or a mixture of glass network formers and glass network intermediates. The ion elements E are chosen from the group of nitrogen N, oxygen O, fluorine F or a mixture thereof.

In some embodiments, gas cluster ion beam implantation (GCIB) may be used for implantation of the ion elements E. In GCIB, instead of using singly or multiply charged ions or ionic molecules that are accelerated towards a target under high electric field in conventional ion implantation, accelerated charged clusters of atoms, or gas clusters, are used, With this technique, the layer stack 110 to be patterned is exposed to a bombardment with gas clusters of a few hundred up to several thousands of gaseous atoms or molecules. At the moment of impact, the energy released per atom is very low, typically less than 10 eV, thereby creating low damage surface or shallow penetration of the active species into the substrate. Although the energy per atom is low, the energy density near the surface is very high and the heat released at the point of impact is very high, hence providing the energy for enhancing the chemical reactions and/or material evaporation. According to embodiments, the metal/metalloid layer 106 comprising metal elements Z is thus bombarded with ion elements E by GCIB implantation. At the same time, the surface of the metal/metalloid layer 106 receives—due to the use of GCIB—a high, but surface restricted thermal budget. In this way, the oxygen O or fluoride N implanted into and metal/metalloid elements Z 108 diffused into the outer parts 121, 122 of the top ferromagnetic layer 103 are intermixed at a temperature which allows direct metal-oxide matrix formation in the outer parts of the top ferromagnetic layer. It is an advantage of using GCIB implantation that a subsequent annealing step to stabilize the metal/metalloid-oxide matrix is not necessary anymore.

After implantation, the intermediate structure having at least partially amorphous material 109 that includes one of metal/metalloid-oxide, metal/metalloid-fluoride-matrix, metal/metalloid-nitride, or a mixture thereof, in the outer top parts of the top ferromagnetic layer 103, may be annealed. For example, the intermediate structure can be laser-annealed in the temperature range between about 400 and about 700 degrees Celsius.

It will be appreciated that the diffusion of the metal/metalloid elements Z and the ion elements E can take place both during the implantation of the ion elements and, if present, during the annealing of the at least partially amorphous material or matrix 109. Annealing can further diffuse the elements into the ferromagnetic layers after the implantation step. Metal/metalloid elements Z 108 from the metal/metalloid layer 106 are thus driven into the outer parts of the top ferromagnetic layer 103 during both the implantation step of oxygen and/or fluorine and/or nitrogen and a later annealing step.

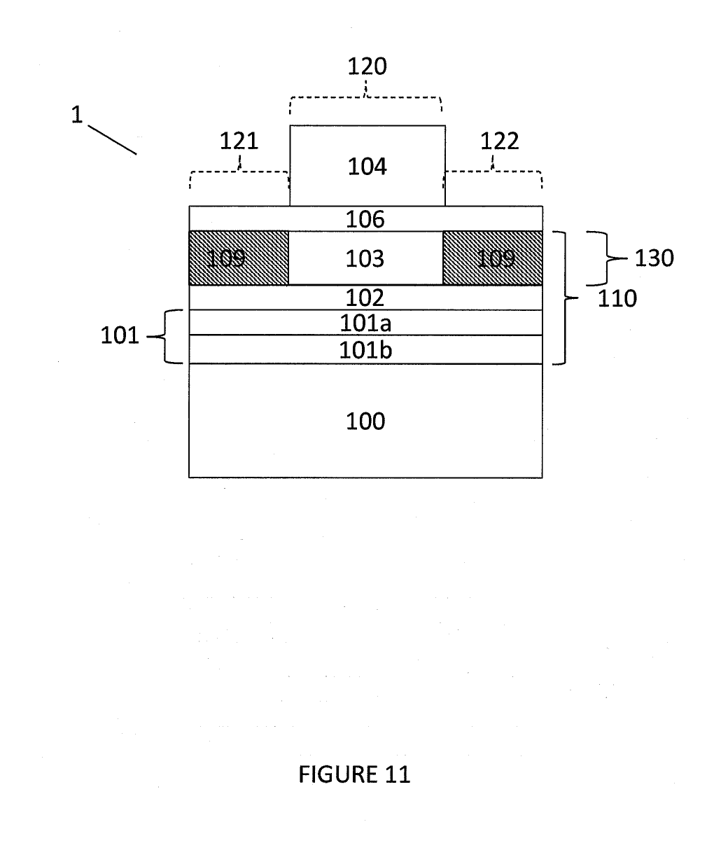

FIG. 11 schematically shows the MTJ stack 1 after conversion of outer parts 121, 122 of the top ferromagnetic layer. As described in the foregoing, the underlying layers may also be converted, including, for example, the outer parts 121, 122 of the barrier layer 102 and/or of the bottom ferromagnetic layer 101. It will be appreciated that various process parameters can be adapted such that the ion elements E and metal/metalloid elements Z 180 are designed to diffuse through the different layers. These parameters include, for example, increasing the thickness of the metal layer 106, using a higher temperature in the annealing step or using higher implantation energies in the implantation step.

After the conversion of the ferromagnetic layers, an etching step of the outer parts may be performed to reduce the width of the MTJ element 1. An exemplary final structure of the MTJ element after an etching step shown in FIG. 11 will be similar to the one shown in FIG. 6, except for the presence of the metal layer 106 on the stack if the metal layer 106 is formed before the hard mask 104. Optionally, this metal layer 106 may be removed before narrowing the converted outer parts 109. Small part of the converted ferromagnetic material, i.e. of the at least partially amorphous glass material 109 (hatched parts) of the outer parts 122 remains present in the final MTJ element 1 in order to protect the middle part of the ferromagnetic layers during further steps involving other etching or other detrimental process steps.

Using additional process steps (such as for example typical back-end-of-line (BEOL) process steps), known for a person skilled in the art, the MTJ stack 1 may further be finalized towards an end-product, such as an STT-MRAM device.

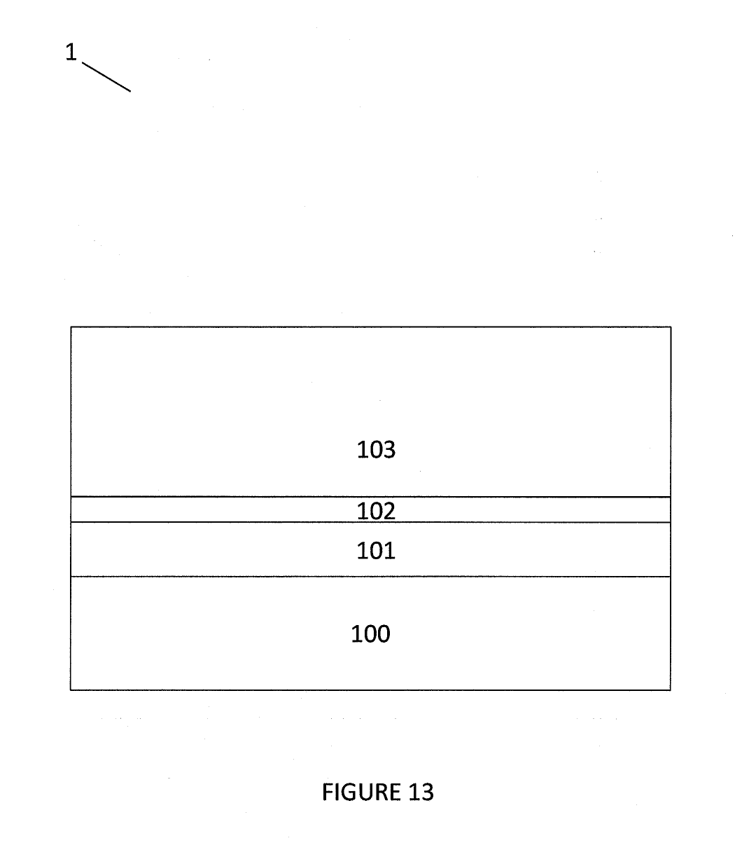

FIGS. 13-16 show intermediate structures representing different stages of fabrication of a magnetic memory device comprising patterned MTJ stacks patterned according to some other embodiments of the present disclosure. In the illustrated embodiment, unlike previously described embodiments, the intermediate structures have a plurality of stacks that are being formed. Referring to FIG. 13, similar to as described above with respect to FIG. 1, a stack of layers 101, 102, and 103 is provided on a substrate 100. The substrate can comprise a seed layer and/or a bottom electrode of the magnetic memory device. The stack of layers includes a tunnel barrier layer 102 sandwiched between a top ferromagnetic layer 103 and a bottom ferromagnetic layer 101 (FIG. 13). Referring to FIG. 14, according to some embodiments, the stack of layers is patterned using hardmasks 104A and 104B, thereby forming a left MTJ stack (A) and a right MTJ stack (B). For both stacks, outer 121A, 122A, 121B, 122B and middle parts 121A, 121B may be defined, similar to as described above with respect to FIG. 2. Before converting the outer parts 121A/B and 122A/B of the top ferromagnetic layers 103A/B, the ferromagnetic layers 103A/B can be partially removed to thin the outer parts, compared to the as-deposited thickness of the top ferromagnetic layers 103A/B. The thickness of the middle parts 102A/B of the top ferromagnetic layers 103A/B, and of the stacks 110A/110B, thus remains unchanged (FIG. 14).

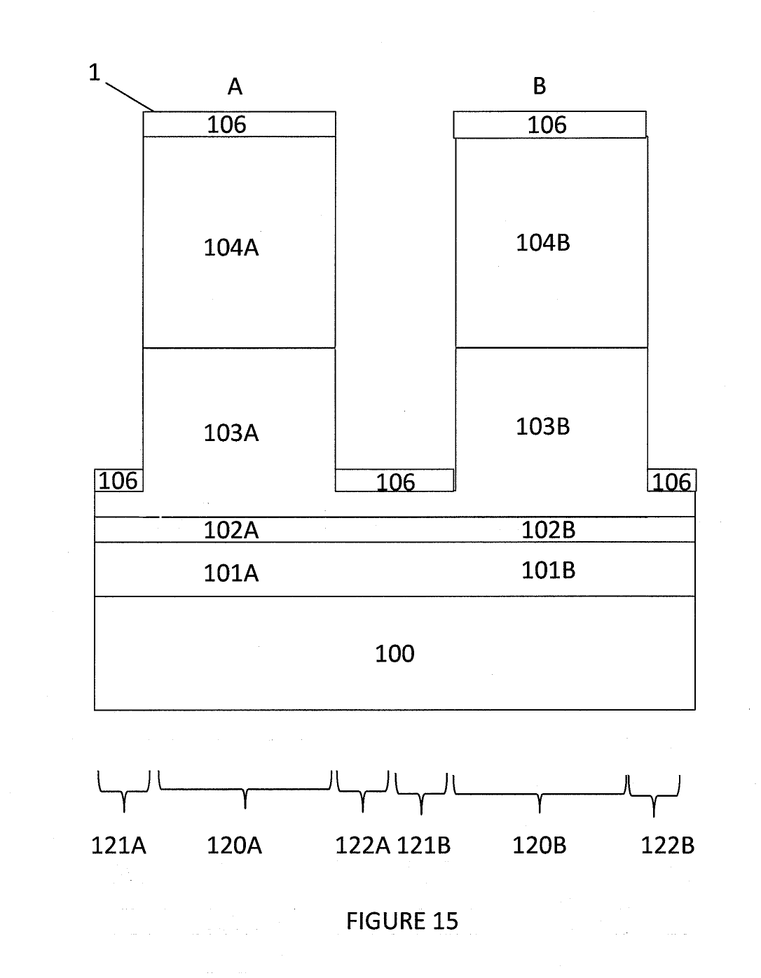

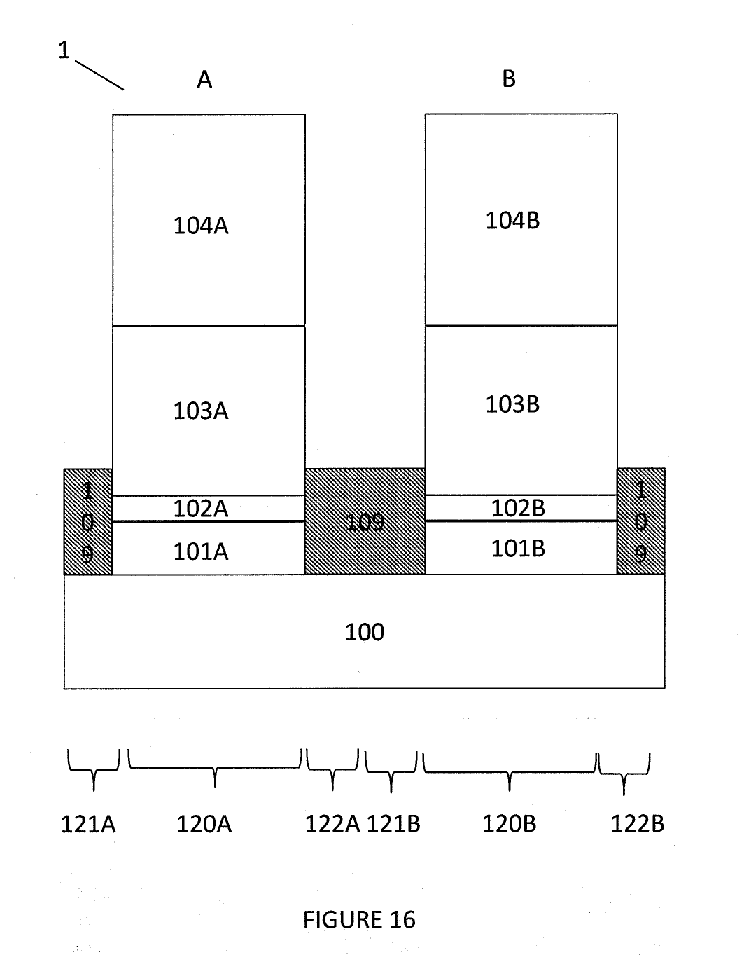

Referring to FIG. 16, after partially patterning the top ferromagnetic layers 103A/103B, the exposed ferromagnetic layers in the outer parts 121A, 122A, 121B, 122B of the stacks 110A/110B are converted into insulating layers 109. This conversion may be done according to embodiments similar to as described above, i.e. by providing a metal layer 106 (with metal elements Z) at least on the outer parts 121,122 of the top ferromagnetic layer 103, and performing a GCIB implantation of ion elements E at least into the metal layer 106. FIG. 15 illustrates the embodiment where the hard mask 14 is formed prior to the metal layer 16, similar to as described above with respect to FIG. 9.

Still referring to FIG. 16, thus formed MTJ stack A and MTJ stack B are thus isolated from each other by thinning the outer parts and thereafter converting the remaining outer parts into an insulating material.

A second aspect of the disclosure relates to a magnetic tunneling junction (MTJ) element 1.

Referring back, to FIG. 1, a MTJ element 1 includes a tunneling barrier layer 102 sandwiched in between a bottom ferromagnetic layer 101 and a top ferromagnetic layer 103. If the MTJ stack of the element 1 is the so-called bottom-pinned MTJ stack, the bottom ferromagnetic layer includes the hard ferromagnetic layer and the top ferromagnetic layer includes the soft ferromagnetic layer. If the MTJ stack is the so-called top-pinned MTJ stack, the bottom ferromagnetic layer includes the soft ferromagnetic layer and the top ferromagnetic layer includes the hard ferromagnetic layer.

For illustrative purposes only, the illustrated embodiment is a bottom pinned MTJ stack. FIG. 1 shows a MTJ element 1 comprising a tunneling barrier layer 102 sandwiched in between a hard ferromagnetic layer 101—typically comprising a fixed magnetic layer 101a and a pinning layer 101b—and a soft ferromagnetic layer 103. The soft ferromagnetic layer is often also referred to as the free magnetic layer. It will be appreciated that the inventive aspects described herein can be applied to alternative embodiments where the MTJ stack is modified, for example, as in a top-pinned MTJ stack, in which layers 101 and 103 may be interchanged.

Referring back to FIG. 6, is a cross-sectional view illustrating the structure of a patterned MTJ element 1 according to some other embodiments. The MTJ element 1 includes a stack of layers 110 on a substrate 100, the stack of layers 110 comprising a tunneling barrier layer 102 sandwiched in between a bottom ferromagnetic layer 101 and a top ferromagnetic layer 103. The bottom ferromagnetic layer 101 includes a fixed magnetic layer 101a and a pinning layer 101b. The top ferromagnetic layer 103 includes a middle part 103 and outer parts 109 aside of the middle part 103. The middle part 103 is ferromagnetic and includes ferromagnetic material FM whereby the outer parts 109 are insulating and comprise an glass-like insulator matrix. The glass-like insulator matrix includes the ferromagnetic material FM, ion elements E and metal/metalloid elements Z. The outer parts 109 of the top ferromagnetic layer 103 are thus electrically insulating, whereas the middle part 103 is electrically active, more specifically ferromagnetic. According to embodiments, also the bottom ferromagnetic layer 101 includes a middle part and two outer parts aside of the middle part. Optionally, the middle part is ferromagnetic and includes ferromagnetic material elements whereby the outer parts are insulating and comprise a mixture of the ferromagnetic material of the middle part, ion elements E and metal/metalloid elements Z. A final structure of the MTJ element after the final etching step is shown in FIG. 16.

An exemplary magnetic tunnel junction (MTJ) element 1 according to embodiments of the present disclosure includes, for example, a CoFeB reference layer 101 formed on a seed layer (e.g. Ta or Ru) substrate 100. The MTJ element 1 additionally includes a MgO tunneling barrier layer 102 formed on the CoFeB reference layer 101, and further includes a soft layer 103 formed on the MgO tunneling barrier 102. The soft layer 103 has a middle part 120 formed of CoFeB and outer parts 109 formed of, e.g., FM_{Y}Z_{X}O_{Z}, where FM can include one or more of Co and Fe, where Z can include one or more chosen from the group of glass network formers such as Si, Ge, P, V and As, among other network formers, and from the group of glass intermediates such as Al, Sb, Zr, Ti, Pb, Be and Zn, among other glass intermediates, or a mixture thereof, and O is oxygen, whereby 0<z,x,y and x+y+z=1.

The foregoing description details certain embodiments of the invention. It will be appreciated, however, that no matter how detailed the foregoing appears in text, the invention may be practiced in many ways. It should be noted that the use of particular terminology when describing certain features or aspects of the disclosure should not be taken to imply that the terminology is being re-defined herein to be restricted to including any specific characteristics of the features or aspects of the disclosure with which that terminology is associated.

What is claimed is:

1. A method of patterning a magnetic tunnel junction (MTJ) element, comprising:
providing a stack of layers on a substrate, the stack comprising a tunneling barrier layer interposed between a top ferromagnetic layer and a bottom ferromagnetic layer;
defining outer parts surrounding a middle part for each of the top ferromagnetic layer, the tunneling barrier layer, and the bottom ferromagnetic layer; and
incorporating metal or metalloid elements (Z) together with ion elements (E) into the outer parts of the top ferromagnetic layer, thereby modifying the outer parts of the top ferromagnetic layer to have electrically insulating properties.

2. The method of claim 1, further comprising incorporating the metal or the metalloid elements (Z) together with the ion elements (E) into the outer parts of the bottom ferromagnetic layer, thereby modifying the outer parts of the bottom ferromagnetic layer to have electrically insulating properties.

3. The method of claim 1, wherein the insulating properties are amorphous glass-like properties.

4. The method of claim 1, wherein incorporating the metal or the metalloid elements (Z) together with the ion elements (E) comprises:
providing on the top ferromagnetic layer a metal layer comprising the metal or the metalloid elements (Z);
implanting the ion elements (E) into the metal layer; and
diffusing the metal or the metalloid elements (Z) and the ion elements (E) into at least one of the outer parts of the top ferromagnetic layer and the outer parts of the bottom ferromagnetic layer.

5. The method of claim 1, further comprising annealing the MTJ element after incorporating the metal or the metalloid elements (Z) together with the ion elements (E).

6. The method of claim 5, wherein annealing comprises annealing using a laser.

7. The method of claim 1, further comprising: after providing the stack of layers and before incorporating the metal or the metalloid elements (Z) together with the ion elements (E), providing a hard mask on the middle part of the top ferromagnetic layer.

8. The method of claim 1, wherein the ion elements E are incorporated in the outer parts using gas-clustered ion beams.

9. The method of claim 1, wherein the ion elements E are chosen from the group consisting of nitrogen (N), oxygen (O) and fluorine (F).

10. The method of claim 1, wherein the metal or the metalloid elements (Z) includes a species chosen from the group consisting of glass network formers, glass network intermediates or a mixture thereof.

11. The method of claim 1, further comprising patterning the stack after incorporating the metal or the metalloid elements (Z) together with the ion elements (E).

12. The method of claim 1, further comprising thinning an upper portion of the top ferromagnetic layer before incorporating the metal or the metalloid elements (Z) together with the ion elements (E).

13. A magnetic tunnel junction (MTJ) element comprising:
a stack of layers comprising a tunneling barrier layer interposed between a top ferromagnetic layer and a bottom ferromagnetic layer,
wherein the top ferromagnetic layer comprises a ferromagnetic portion including a ferromagnetic material and an insulating portion laterally surrounding the ferromagnetic portion,
wherein the insulating portion comprises an amorphous glass including a mixture of the ferromagnetic material, an oxidizing element and a glass-forming element including a metal/metalloid element.

14. The MTJ element of claim 13, wherein the mixture includes at least one material selected from a group consisting of an amorphous insulating metal/metalloid-oxide, a metal/metalloid-fluoride and a metal/metalloid-nitride.

15. The MTJ element of claim 13, wherein the glass-forming element includes at least one element chosen from the group consisting of Si, Ge, P, V, As, Al, Sb, Zr, Ti, Pb, Be, and Zn.

16. A method of forming a magnetic tunnel junction (MTJ), comprising:
providing an MTJ material stack comprising a ferromagnetic material;
forming a protective mask layer to cover an active area of the MTJ material stack;
incorporating a glass-forming element into exposed portions of the ferromagnetic material, wherein the glass-forming element comprises a metal or a metalloid element; and
at least partially amorphizing the exposed portions of the ferromagnetic material,
wherein at least partially amorphizing transforms the exposed portions of the ferromagnetic material into an electrical insulator.

17. The method of claim 16, wherein the glass-forming element is chosen from the group consisting of Si, Ge, P, V, As, B Al, Sb, Zr, Ti, Pb, Be and Zn.

18. The method of claim 17, further comprising:
incorporating an oxidizing element chosen from the group consisting of oxygen, nitrogen and fluorine,
wherein at least partially amorphizing comprises forming a glass having an amorphous network formed by the glass-forming element, the oxidizing element and an element of the ferromagnetic material.

19. The method of claim 18, wherein at least one of the oxidizing element and the glass-forming element is implanted into the ferromagnetic material.

20. The method of claim 16,
wherein the MTJ material stack further comprises a bottom ferromagnetic material and a dielectric tunneling barrier interposed between the ferromagnetic material and the bottom ferromagnetic material,
wherein the method further comprises at least partially amorphizing a portion of the bottom ferromagnetic material overlapping with the exposed portions of the ferromagnetic material, thereby transforming the portion of the bottom ferromagnetic material into an electrical insulator.
